(19) United States
(12) Patent Application Publication
(10) Pub. No.: US 2008/0258225 A1
(43) Pub. Date: Oct. 23, 2008

(54) MOS TRANSISTORS HAVING HIGH-K OFFSET SPACERS THAT REDUCE EXTERNAL RESISTANCE AND METHODS FOR FABRICATING THE SAME

(75) Inventors: Frank (Bin) YANG, Mahwah, NJ (US); Michael HARGROVE, Clinton Corners, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/738,135

(22) Filed: Apr. 20, 2007

(51) Int. Cl. H01L 29/94; H01L 21/4763

(52) U.S. Cl. 257/364; 438/595; 257/E21.495; 257/E29.345

(57) ABSTRACT

MOS transistors having high-k spacers and methods for fabricating such transistors are provided. One exemplary method comprises forming a gate stack overlying a semiconductor substrate and forming an offset spacer about sidewalls of the gate stack. The offset spacer is formed of a high-k dielectric material that results in a low interface trap density between the offset spacer and the semiconductor substrate. First ions of a conductivity-determining impurity type are implanted into the semiconductor substrate using the gate stack and the offset spacer as an implantation mask to form spaced-apart impurity-doped extensions.

### FIELD OF THE INVENTION

The present invention generally relates to semiconductor devices and methods for fabricating semiconductor devices, and more particularly relates to MOS transistors having high-k offset spacers that reduce external resistance and methods for fabricating MOS transistors having high-k offset spacers.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). An MOS transistor includes a gate electrode as a control electrode that is formed on a semiconductor substrate and spaced-apart source and drain regions formed within the semiconductor substrate and between which a current can flow. A control voltage applied to the gate electrode controls the flow of current through a channel in the semiconductor substrate between the source and drain regions beneath the gate electrode. The MOS transistor is accessed via a conductive contact formed on the source and drain regions. The ICs are usually formed using both P-channel FETs (PMOS transistors) and N-channel FETs (NMOS transistors) and the IC is then referred to as a complementary MOS or CMOS integrated circuit (IC).

Within an MOS transistor, resistance is associated with each region of the transistor from the conductive contact to the channel region. As the resistance of the transistor increases, the drive current flow through the transistor decreases and, hence, the device performance degrades. This transistor resistance can be expressed by the following equation:

R(transistor)=R(external)+R(channel),

where R(channel) represents the resistance of the channel region under the gate electrode in the semiconductor substrate and R(external) represents the resistance from the conductive contact to the channel on both source and drain sides in the semiconductor substrate. There is a continuing trend to incorporate more and more circuitry on a single IC chip. To incorporate the increasing amount of circuitry, the size of each individual device in the circuit and the size and spacing between device elements (the feature size) must decrease. However, as device size continues to decrease in size, particularly below 45 nm node technology, external resistance becomes more and more dominant in affecting advanced CMOS device drive current. This is because, while the channel resistance decreases with gate electrode length, the external resistance increases due to reduced contact window size and shallower junction depth. For example, for a 45 nm node technology PMOS, the external resistance and the channel resistance typically can be about the same, that is, about 300 ohm-μm. For a 32 nm node technology PMOS, it is expected that the channel resistance will be about half of the channel resistance of the 45 nm PMOS because of continued efforts to enhance channel mobility and further reduction of the gate electrode length. However, the external resistance is expected to increase by about 30%.

Accordingly, it is desirable to provide MOS transistors that exhibit reduced external resistance for smaller node technology so that transistor performance is not limited by high external resistance instead of channel mobility. In addition, it is desirable to provide methods for fabricating such MOS transistors. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating an MOS transistor in accordance with an exemplary embodiment of the present invention is provided. The method comprises forming a gate stack overlying a semiconductor substrate and forming an offset spacer about sidewalls of the gate stack. The offset spacer is formed of a high-k dielectric material that results in low interface trap density between the high-k dielectric material and the semiconductor substrate. First ions of a conductivity-determining impurity are implanted into the semiconductor substrate using the gate stack and the offset spacer as an implantation mask to form spaced-apart impurity-doped extensions.

A method for fabricating an MOS transistor exhibiting low external resistance in accordance with an exemplary embodiment of the present invention is provided. The method comprises providing a semiconductor substrate having a surface of a first conductivity type thereon and fabricating a gate stack overlying the semiconductor substrate. A layer of high-k spacer-forming material is deposited overlying the gate stack and the semiconductor substrate. The high-k spacer-forming material results in low interface trap density between the high-k spacer-forming material and the semiconductor substrate. The layer of high-k spacer-forming material is anisotropically etched to form a high-k offset spacer disposed adjacent to sidewalls of the gate stack. Impurity dopants of a second conductivity type are implanted into the semiconductor substrate using the gate stack and the high-k offset spacer as an implantation mask. An additional spacer is formed proximate to the high-k offset spacer and a metal silicide-forming material is deposited on the semiconductor substrate and heated to form metal silicide on the semiconductor substrate.

An MOS transistor in accordance with an exemplary embodiment of the present invention is provided. The MOS transistor comprises a gate insulator disposed on a semiconductor substrate. A gate electrode overlies the gate insulator and a high-k offset spacer is disposed adjacent to sidewalls of the gate electrode. The high-k offset spacer comprises a high-k material that results in a low interface trap density between the high-k offset spacer and the semiconductor substrate. Source and drain extensions are disposed within the semiconductor substrate and are aligned with the gate electrode and the high-k offset spacer. An additional spacer is disposed adjacent to the high-k offset spacer. Source and drain regions are disposed within the semiconductor substrate and are aligned with the gate electrode, the high-k offset spacer, and the additional spacer.

### BRIEF DESCRIPTION OF THE DRAWINGS

The present invention will hereinafter be described in conjunction with the following drawing figures, wherein like numerals denote like elements, and wherein:

FIG. 1 is a cross-sectional view of a conventional MOS transistor with various components of external resistance;

FIG. 2 is a graph illustrating the dependence of external resistance of an MOS transistor on gate overdrive voltage;

FIG. 3 is a graph illustrating the dependence of the various components of external resistance of the MOS transistor of FIG. 1 on gate overdrive voltage;

FIG. 4 is a cross-sectional view of an MOS transistor in accordance with an exemplary embodiment of the present invention;

FIG. 5 is a graph illustrating the dependence of the various components of external resistance of the MOS transistor of FIG. 4 on gate overdrive voltage;

FIG. 6 is a cross-sectional view of an MOS transistor in accordance with another exemplary embodiment of the present invention;

FIGS. 7-12 illustrate, in cross section, a method for fabricating the MOS transistor of FIG. 4 in accordance with an exemplary embodiment of the present invention; and

FIGS. 13-15 illustrate, in cross section, a method for fabricating the MOS transistor of FIG. 6 in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

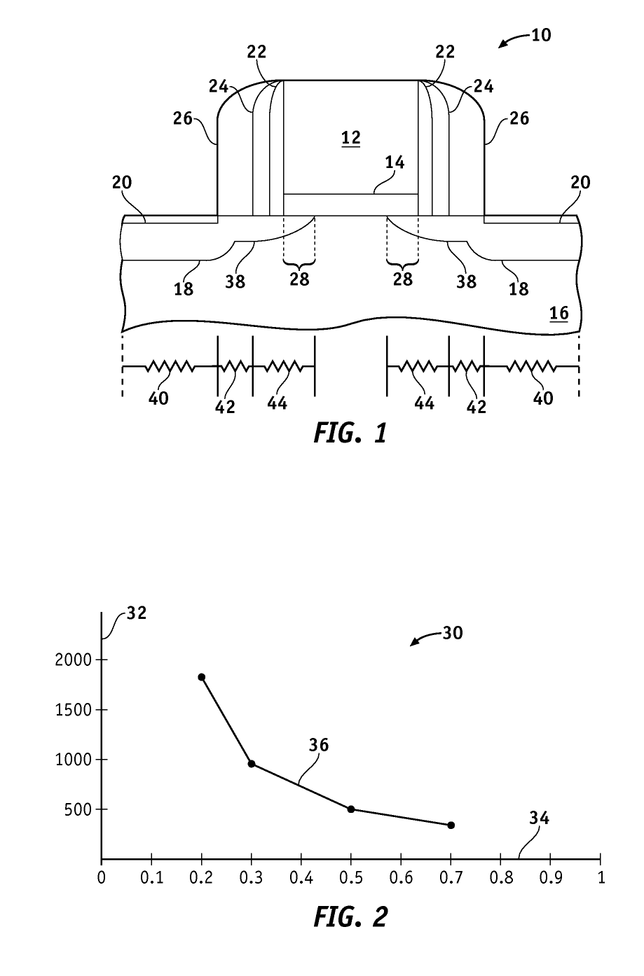

FIG. 1 schematically illustrates various components of the external resistance of a conventional MOS transistor 10. As illustrated in FIG. 1, MOS transistor 10 comprises a gate electrode 12 overlying a gate insulator 14, which are disposed on a semiconductor substrate 16. The transistor 10 also comprises shallow source and drain extensions 38 and deep source and drain regions 18 formed within the semiconductor substrate 16. Conductive contacts 20 are disposed on the source/drain regions 18. Typical with most conventional transistors, MOS transistor 10 has a reoxidation sidewall spacer 22, which is formed by subjecting the gate electrode to high temperature in an oxidizing ambient and which has a thickness of about 3 to 4 nm. A second spacer 24, often referred to as an offset spacer, is disposed adjacent to the reoxidation sidewall spacer 22 and has a thickness of about 10 to about 20 nm. The reoxidation spacer 22 and the offset spacer 24 are used along with the gate electrode as an ion implantation mask for formation of source and drain extensions 38. A third spacer 26, typically a silicon nitride “final spacer,” is disposed adjacent the offset spacer and is used as an ion implantation mask for formation of deep source and drain regions 18. The final spacer also separates the conductive contact 20 from the gate electrode 12 to prevent an electrical shorting of the gate to either the source or drain regions 18 of the transistor.

The external resistance of MOS transistor 10 can be expressed by the following equation:

R(external)=2R(source/drain)=2(Rc+Rs+Rspr+Rov),

where R(source/drain) is the resistance from the conductive source and drain contacts to the MOS transistor channel, including that portion of the source or drain underlying the gate insulator. The component Rc 40 of the external resistance is illustrated in FIG. 1 as the contact resistance from the conductive contact 20 to the region of the semiconductor substrate below the conductive contact 20. The resistance of the semiconductor substrate below the final spacer 26 is illustrated as the component Rs 42. The resistance within the source/drain extensions 38, that is, the region of the semiconductor substrate below the offset spacer 24, the reoxidation sidewall spacer 22, and an overlap region 28, where the gate electrode overlaps the source/drain extension 38, is designated Rspr+Rov 44.

Recent research indicates that external resistance is not a fixed value, but strongly depends on gate overdrive voltage (V_{god}). V_{god} is defined by the equation:

V_{god}=V_{gs}−Vₜₗᵢₙ,

where V_{gs} is gate-source voltage and Vₜₗᵢₙ is the threshold voltage Vₜ of the MOS transistor in the linear region of operation. At a low V_{god}, external resistance is much higher than the channel resistance and dominates the device drive current. FIG. 2 is a graph 30 of the dependence of external resistance (ohm-μm), represented by y-axis 32, on V_{god} (V), represented on x-axis 34, for a typical 45 nm node technology PMOS. The curve 36 of FIG. 2 illustrates that at a low V_{god}, external resistance is much higher than it is at a high V_{god}. For example, at V_{god}=0.3 V, R(external) is as high as 950 ohm-μm, while R(channel) (not shown) for such a device typically is about 300 ohm-μm. At V_{god}=0.7 V, R(external) reduces significantly to about 360 ohm-μm, while R(channel) (not shown) is about 200 ohm-μm. Because a V_{god} of about 0.3 V roughly corresponds to the gate bias voltage for I_low (at V_{gs}=0.5 V, Vₛ=0V, V_{d}=1V) and a V_{god} of about 0.7 V roughly corresponds to the gate bias voltage for I_high (at V_{gs}=1 V, Vₛ=0V, V_{d}=0.5V), both low V_{god} and high V_{god} are critical for the effective current I_{eff} as I_{eff}=(I_low+I_high)/2. Practically, I_{eff} is a better representation of transistor performance than I_{ON} as I_{eff} is the average channel current when the transistor switches from off-state to on-state, while I_{ON} only represents the transistor current at on-state.

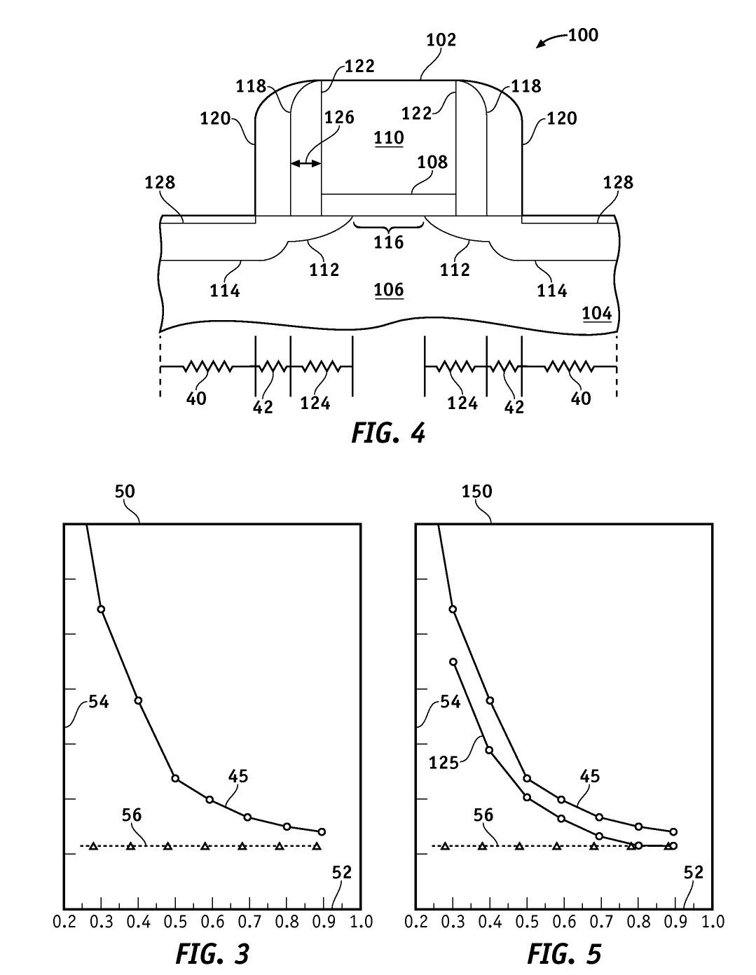

Without intending to be bound by any theory, it is believed that the strong dependence on V_{god} mainly is ascribed to the component “Rspr+Rov” of the external resistance attributed to the resistance of the semiconductor substrate in the gate overlap region (Rov) and the regions under the oxide sidewall spacers and the offset spacers (Rspr). FIG. 3 is a graph 50 simulating the relationship between V_{god} (V), represented on the x-axis 52, and the various components of the external resistance (ohm-μm), represented on the y-axis 54, for a typical PMOS transistor having a silicon oxynitride gate insulator. As illustrated, the resistance component Rspr+Rov 44, illustrated by curve 45, is higher than the sum of contact resistance Rc and resistance Rs, represented by curve 56, particularly at low V_{god}. The resistance component Rspr+Rov 44 decreases significantly as V_{god} increases. In contrast, the sum 56 of contact resistance Rc and resistance Rs do not change with V_{god}. This is understandable because the charge density in the Rspr+Rov regions of the semiconductor substrate can be modulated by V_{god} due to the close proximity to the gate electrode 12 while V_{god} cannot modulate the charge density in the regions under the final spacer and the contact. In addition, because the doping concentration is much lower in the source/drain extensions than in the source/drain regions, it is expected that the resistance component Rspr+Rov would be dominantly higher than the components Rs and Rc. Thus, by decreasing the resistance component Rspr+Rov, the external resistance can be reduced, particularly at low V_{god}.

FIG. 4 is a cross-sectional view of a semiconductor device 100 having an MOS transistor 102 in accordance with an exemplary embodiment of the present invention. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate. MOS transistor 102 can be a PMOS transistor or an NMOS transistor. While semiconductor device 100 is illustrated with only one MOS transistor, it will be appreciated that semiconductor device 100 may have any number of NMOS transistors and/or PMOS transistors. Those of skill in the art will appreciate that device 100 may include a large number of such transistors as required to implement a desired circuit function.

MOS transistor 102 is fabricated on a semiconductor substrate 104 which can be either a bulk silicon wafer as illustrated or a thin silicon layer on an insulating substrate (SOI). At least a surface portion 106 of the semiconductor substrate 104 is doped with P-type conductivity determining impurities for the fabrication of an NMOS transistor or with N-type conductivity determining impurities for the fabrication of a PMOS transistor. Portion 106 can be impurity doped, for example, by the implantation and subsequent thermal annealing of dopant ions such as boron or arsenic.

MOS transistor 102 includes a gate insulator 108 formed at the surface of the semiconductor substrate 104. The gate insulator 108 may be a thermally grown silicon dioxide formed by heating the substrate in an oxidizing ambient, or may be a deposited insulator such as silicon oxide, silicon nitride, or the like. The gate insulator 108 is typically 1-10 nanometers (nm) in thickness. A gate electrode 110 overlies the gate insulator 108. The gate electrode may be formed of polycrystalline silicon or other conductive material such as metal. Source and drain extensions 112 and deeper source and drain regions 114 are disposed within silicon substrate 104 and are separated by a channel region 116 disposed below the gate electrode 110 within the silicon substrate 104. Conductive contacts 128 are disposed on the source/drain regions 114. Conductive contacts 128 may comprise, for example, a metal silicide.

MOS transistor 102 further comprises “high-k” offset spacers 118 that are disposed about sidewalls 122 of gate electrode 110 and that are comprised of material having a high dielectric constant (“high-k material”) and that results in “low interface trap density” between the deposited high-k material and the substrate. As used herein, the terms “high dielectric constant” material or “high-k” material means a material having a dielectric constant greater than the dielectric constant of silicon dioxide (which is about 3.9). As used herein, the term “low interface trap density” means an interface trap density of no greater than 1×10¹¹ cm⁻². Examples of high-k materials that may be used to form high-k offset spacers 118 include aluminum oxide (Al₂O₃), hafnium oxide (HfO₂), hafnium oxynitride (HfON), hafnium silicate (HfSiO₄), zirconium oxide (ZrO₂), zirconium silicate (ZrSiO₄), yttrium oxide (Y₂O₃), lanthanum oxide (La₂O₃), cerium oxide (CeO₂), titanium oxide (TiO₂), and the like, and combinations thereof, which offer both high dielectric constant and low interface trap density. The high-k offset spacers 118 have a thickness, indicated by double-headed arrow 126, sufficient to result in an increase in capacitance of the semiconductor substrate underlying the high-k spacer. In one exemplary embodiment of the invention, the high-k offset spacers 118 have a thickness 126 no greater than about 16 nm. In another exemplary embodiment, the high-k offset spacers 118 have a thickness in the range of about 10 to about 16 nm. Additional spacers 120 formed of an insulating material, such as, for example, silicon dioxide or silicon nitride, are disposed proximate to the high-k offset spacers 118. It will be appreciated that MOS transistor 102 may have any other number or types of spacers as required to achieve a desired device performance.

FIG. 5 is a graph 150 simulating the relationship between V_{god} (V), represented on the x-axis 52, and the various components of the external resistance (ohm-μm), represented on the y-axis 54, for a typical PMOS transistor 102 having high-k offset spacers 118 with thickness 126 equal to about the combined thickness of the conventional zero spacer and the reoxidation sidewall spacer of MOS transistor 10 of FIG. 1. Referring to FIGS. 4 and 5, the resistance component Rspr+Rov 124, illustrated by curve 125, for a PMOS transistor 102 having a high-k offset spacer is less than the resistance component Rspr+Rov 44, illustrated by curve 45, for the MOS transistor 10 of FIG. 1, particularly at low V_{god}. At high V_{god}, the resistance component Rspr+Rov 124 is almost equal to the sum Rc+Rs, illustrated by curve 56, such that R(external) is no longer dominated by Rspr+Rov.

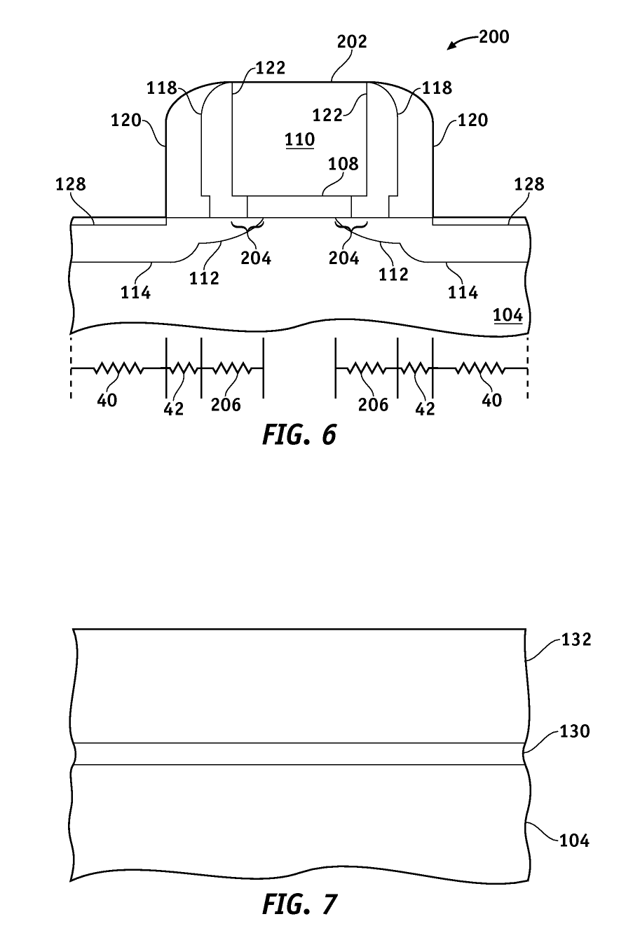

FIG. 6 illustrates a semiconductor device 200 having an MOS transistor 202 in accordance with another exemplary embodiment of the present invention. MOS transistor 202 is similar to MOS transistor 102 of FIG. 4, as high-k offset spacers 118 replace the offset spacers 24 and reoxidation sidewall spacers 22 of MOS transistor 10 of FIG. 1; however, the gate insulator 108 of MOS transistor 102 is slightly undercut relative to the gate electrode 110. Thus, not only are the offset spacers and reoxidation sidewall spacers replaced by high-k offset spacers 118, but high-k offset spacers 118 also replaces a portion of the gate insulator 108 in the overlap region 204, which is the region of the source and drain extension 112 that is overlapped by gate electrode 110. By using high-k material in both the overlap region 204 and the offset spacers 118, the overlap capacitance between the semiconductor substrate and the gate electrode can be substantially increased. The direct overlap capacitance from overlap region 204 is increased by almost a factor of the ratio of high-k dielectric constant to the dielectric constant of the thermal silicon dioxide with a dielectric constant of 3.9. Accordingly, if, for example, the high-k offset spacers 118 are of a material having a dielectric constant of about 20, the direct overlap capacitance can be increased by a factor of about 5 (approximately 20 divided by 3.9). Thus, the semiconductor substrate under the high-k direct overlap will be roughly about 5 times more conductive and the resistance component Rov will be decreased substantially. In an embodiment, the gate insulator 108 is undercut so that the high-k offset spacer 118 substantially overlaps the overlap region 204. In another embodiment of the invention, the gate insulator is undercut about 3 nm. Thus, not only will resistance component Rspr be decreased, as described above with reference to MOS transistor 102 of FIG. 4, but resistance component Rov will be reduced even more substantially, further reducing the overall resistance component Rspr+Rov 206. In addition, by adjusting the type of fixed charge in the high-k offset spacer 118 in the overlap region 204, Vₜ in the overlap region 204 can be significantly lower than the Vₜ in the channel, thus leading to higher accumulation charge in the entire overlap region 204 and further reducing Rspr+Rov.

FIGS. 7-12 illustrate, in cross section, a method for forming an MOS transistor, such as MOS transistor 102 of FIG. 4, in accordance with an exemplary embodiment of the invention. Various steps in the manufacture of MOS components are well known and so, in the interest of brevity, many conventional steps will only be mentioned briefly herein or will be omitted entirely without providing the well known process details.

Referring to FIG. 7, the method begins by forming a gate insulator material 130 overlying a semiconductor substrate 104. The semiconductor substrate is preferably a silicon substrate wherein the term “silicon substrate” is used herein to encompass the relatively pure silicon materials typically used in the semiconductor industry as well as silicon admixed with other elements such as germanium, carbon, and the like. Alternatively, the semiconductor substrate can be germanium, gallium arsenide, or other semiconductor material. The semiconductor substrate will hereinafter be referred to for convenience, but without limitation, as a silicon substrate. The silicon substrate may be a bulk silicon wafer, or may be a thin layer of silicon on an insulating layer (commonly know as silicon-on-insulator or SOI) that, in turn, is supported by a carrier wafer. The silicon substrate is impurity doped, for example by forming N-type well regions and P-type well regions for the fabrication of P-channel (PMOS) transistors and N-channel (NMOS) transistors, respectively.

In the conventional processing, the layer 130 of gate insulating material can be a layer of thermally grown silicon dioxide or, alternatively (as illustrated), a deposited insulator such as a silicon oxide, silicon nitride, or the like. Deposited insulators can be deposited, for example, by chemical vapor deposition (CVD), low pressure chemical vapor deposition (LPCVD), or plasma enhanced chemical vapor deposition (PECVD). Gate insulator layer 130 preferably has a thickness of about 1-10 nm, although the actual thickness can be determined based on the application of the transistor in the circuit being implemented.

A layer of gate electrode material 132 is formed overlying the gate insulating material 130. In accordance with one embodiment of the invention, the gate electrode material is polycrystalline silicon. The layer of polycrystalline silicon is preferably deposited as undoped polycrystalline silicon and is subsequently impurity doped by ion implantation. The polycrystalline silicon can be deposited by LPCVD by the hydrogen reduction of silane. A layer of hard mask material (not shown), such as silicon nitride or silicon oxynitride, can be deposited onto the surface of the polycrystalline silicon. The hard mask material can be deposited to a thickness of about 50 nm, also by LPCVD.

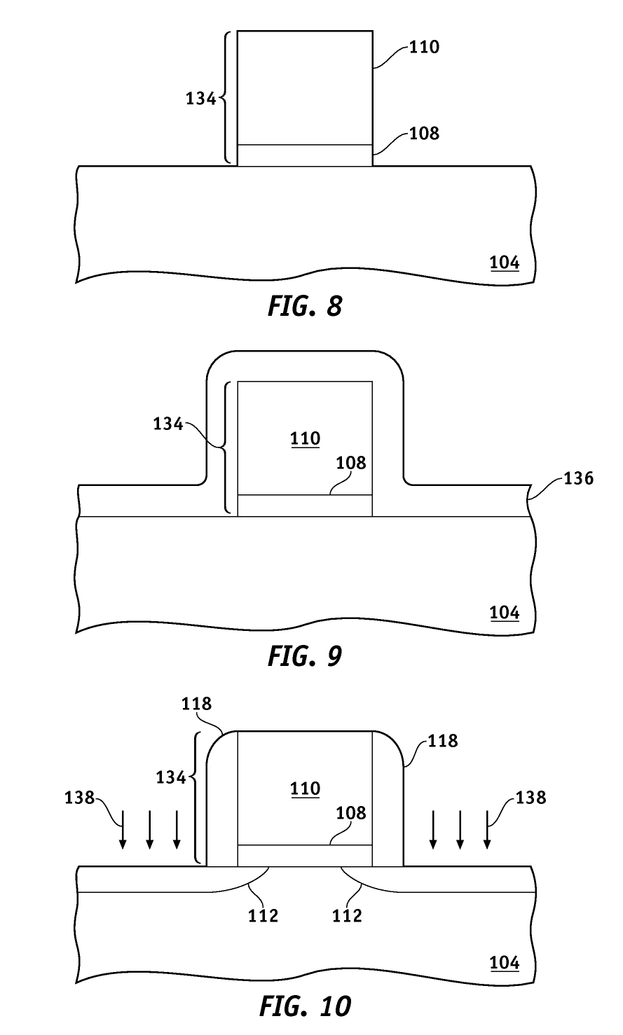

The hard mask layer is photolithographically patterned and the underlying gate electrode material layer 132 and the gate insulating material layer 130 are etched to form a gate stack 134 having a gate insulator 108 and a gate electrode 110, as illustrated in FIG. 8. The polycrystalline silicon can be etched in the desired pattern by, for example, reactive ion etching (RIE) using a Cl⁻ or HBr/O₂ chemistry and the hard mask and gate insulating material can be etched, for example, by RIE in a CHF₃, CF₄, or SF₆ chemistry.

Referring to FIG. 9, a layer 136 of high-k material is conformally deposited overlying the gate stack 134 and the source and drain extensions 112. The high-k dielectric material can be deposited in known manner by, for example, atomic layer deposition (ALD), CVD, LPCVD, semi-atmospheric chemical vapor deposition (SACVD), or PECVD. The high-k material layer 136 is deposited to a thickness so that, after anisotropic etching, high-k offset spacers formed from high-k material layer 136 have a thickness 126 that results in an increase in capacitance coupled to the semiconductor substrate underlying the high-k offset spacer. In one exemplary embodiment of the invention, the high-k offset spacers 118 have a thickness 126 no greater than about 16 nm. In another exemplary embodiment, the high-k offset spacers 118 have a thickness in the range of about 10 to about 16 nm.

The method continues, in accordance with an exemplary embodiment of the invention, with anisotropic etching of the high-k material layer 136 to form high-k offset spacers 118, as illustrated in FIG. 10. The high-k dielectric material can be etched by, for example, RIE using a boron trichloride (BCl₃) chemistry. Gate stack 134 and high-k offset spacers 118 then are used as an ion implantation mask to form source and drain extensions 112 in silicon substrate 104. By using the gate electrode and high-k offset spacers 118 as an ion implant mask, the source and drain extensions are self aligned with the gate stack and high-k offset spacers 118. The source and drain extensions are formed by appropriately impurity doping silicon substrate 104 in known manner, for example, by ion implantation of dopant ions, illustrated by arrows 138, and subsequent thermal annealing. For an N-channel MOS transistor the source and drain extensions 112 are preferably formed by implanting arsenic ions, although phosphorus ions could also be used. For a P-channel MOS transistor, the source and drain extensions are preferably formed by implanting boron ions. Source and drain extensions 112 are shallow and preferably have a junction depth of less than about 20 nm and most preferably less than about 5-10 nm and are heavily impurity doped to about 500 to about 800 ohms per square.

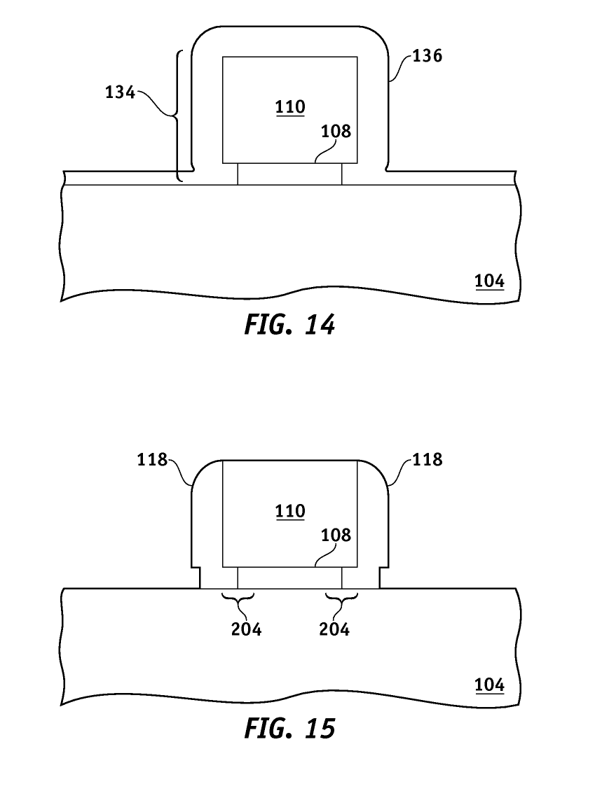

Referring momentarily to FIGS. 13-15, a method for forming high-k offset spacer 118 in accordance with another exemplary embodiment of the present invention is illustrated. Referring to FIG. 13, after the formation of gate stack 134, as illustrated in FIG. 8, gate insulator 108 is partially laterally etched beneath gate electrode 110 to a distance 210 as measured from sidewalls 122 of gate electrode 110. The gate insulator 108 can be etched, for example, by a buffered hydrogen fluoride (BHF) solution. In one exemplary embodiment, the undercut etch can be achieved by a timed wet etch with a relatively low etch rate, such as, for example, about 0.2 nm/sec. The gate insulator 108 can be etched for an appropriate time so that the distance 210 of the underetch approaches the length of overlap region 204. After underetching, the layer 136 of high-k spacer material is conformally deposited as described above, preferably by ALD, overlying the gate stack 134, as illustrated in FIG. 14. Referring to FIG. 15, the layer 136 of high-k spacer material then is etched, as described above, forming high-k offset spacers 118.

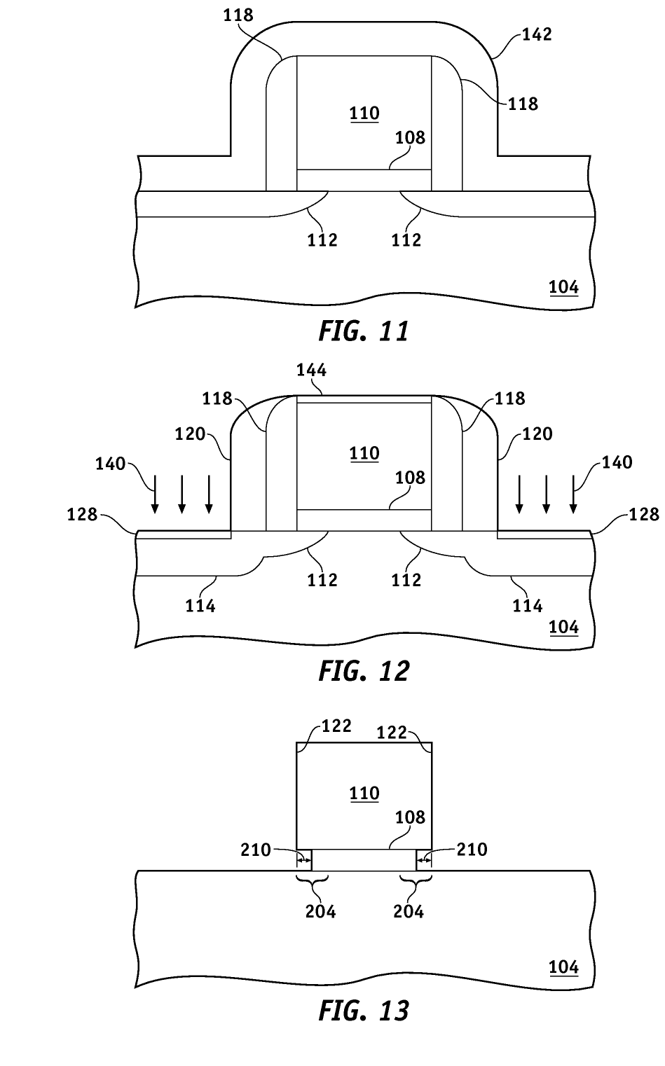

After formation of high-k offset spacers 118, whether by the process shown in FIGS. 9 and 10 or by the process shown in FIGS. 13-15, a layer 142 of additional spacer material is deposited overlying gate electrode 110 and high-k offset spacers 118, as illustrated in FIG. 11. The additional spacer material may comprise insulating material such as, for example, silicon oxide and/or silicon nitride, preferably silicon nitride. Referring to FIG. 12, the layer 142 of additional spacer material is subsequently anisotropically etched, for example by RIE using, for example, a CHF₃, CF₄, or SF₆ chemistry, to form additional spacers 120. The gate stack 134, the high-k offset spacers 118, and additional spacers 120 then are used as an ion implantation mask to form source and drain regions 114 in silicon substrate 104. The source and drain regions are formed by appropriately impurity doping silicon substrate 104 in known manner, for example, by ion implantation of dopant ions, illustrated by arrows 140, and subsequent thermal annealing. For an N-channel MOS transistor, the source and drain regions 114 are preferably formed by implanting arsenic ions, although phosphorus ions could also be used. For a P-channel MOS transistor, the source and drain regions 114 are preferably formed by implanting boron ions.

A blanket layer of silicide-forming metal (not shown) is deposited onto the surface of the source and drain regions 114 and the surface of the gate electrode 110 and is heated, for example by RTA, to form a metal silicide layer 128 at the top of each of the source and drain regions as well as a metal silicide layer 144 on gate electrode 110. In an alternative embodiment, the hard mask used to form gate stack 134 as illustrated in FIG. 8 is not removed after formation of the gate stack so that formation of a metal silicide layer 144 on the gate electrode 110 is prevented. The silicide-forming metal can be, for example, cobalt, nickel, rhenium, ruthenium, or palladium, or alloys thereof and preferably is cobalt, nickel, or nickel plus about 5% platinum. The silicide-forming metal can be deposited, for example, by sputtering to a thickness of about 5-50 nm and preferably to a thickness of about 10 nm. Any silicide-forming metal that is not in contact with exposed silicon, for example the silicide-forming metal that is deposited on the additional spacers 120 or on a hard mask layer, does not react during the RTA to form a silicide and may subsequently be removed by wet etching in a H₂O₂/H₂SO₄ or HNO₃/HCl solution.

Accordingly, MOS transistors having high-k offset spacers that result in low interface trap density and methods for forming such MOS transistors have been provided. With the high-k offset spacers, the MOS transistors exhibit reduced resistance component Rspr+Rov. Reduction of the resistance component Rspr+Rov facilitates reduction in the external resistance of the transistors and, hence, an improvement in the transistors' drive current. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating an MOS transistor, the method comprising the steps of:
forming a gate stack overlying a semiconductor substrate;
forming an offset spacer about sidewalls of the gate stack, wherein the offset spacer is formed of a high-k dielectric material that results in a low interface trap density between the offset spacer and the semiconductor substrate; and
implanting first ions of a conductivity-determining impurity type into the semiconductor substrate using the gate stack and the offset spacer as an implantation mask to form spaced-apart impurity-doped extensions.

2. The method of claim 1, wherein the step of forming an offset spacer comprises the steps of:
depositing a blanket layer of the high-k dielectric material on the gate stack and the semiconductor substrate; and
anisotropically etching the layer of the high-k dielectric material.

3. The method of claim 1, wherein the step of forming an offset spacer about sidewalls of the gate stack comprises the step of forming the offset spacer from at least one material selected from the group consisting of aluminum oxide (Al₂O₃), hafnium oxide (HfO₂), hafnium oxynitride (HfON), hafnium silicate (HfSiO₄), zirconium oxide (ZrO₂), zirconium silicate (ZrSiO₄), yttrium oxide (Y₂O₃), lanthanum oxide (La₂O₃), cerium oxide (CeO₂), titanium oxide (TiO₂), and combinations thereof.

4. The method of claim 1, wherein the step of forming an offset spacer comprises the step of forming the offset spacer having a thickness that is sufficient to cause an increase in capacitance coupled to the semiconductor substrate underlying the offset spacer.

5. The method of claim 4, wherein the step of forming an offset spacer comprises the step of forming the offset spacer having a thickness no greater than about 16 nm.

6. The method of claim 1, further comprising, after the step of implanting, the step of forming an additional spacer adjacent to the offset spacer.

7. The method of claim 6, further comprising, after the step of forming the additional spacer, the step of implanting second ions of the conductivity-determining impurity type into the semiconductor substrate using the gate stack, the offset spacer, and the additional spacer as an implantation mask to form spaced-apart impurity-doped regions and the step of forming a conductive contact on the spaced-apart impurity-doped regions.

8. The method of claim 1, wherein the gate stack comprises a gate insulator disposed on the semiconductor substrate and a gate electrode disposed overlying the gate insulator and wherein the step of forming an offset spacer comprises the steps of:
laterally etching a portion of the gate insulator;
conformally depositing a blanket layer of the high-k dielectric material on the gate stack and the semiconductor substrate; and
anisotropically etching the layer of the high-k dielectric material.

9. The method of claim 8, wherein the step of laterally etching a portion of the gate insulator comprises the step of etching the gate insulator a distance, as measured from one of the sidewalls of the gate stack, that is about equal to a distance that the gate insulator overlaps one of the spaced-apart impurity-doped extensions.

10. The method of claim 8, wherein the step of laterally etching a portion of the gate insulator comprises the step of etching the gate insulator a distance, as measured from one of the sidewalls of the gate stack, in a range of about 3 nm.

11. The method of claim 8, wherein the step of conformally depositing a blanket layer of the high-k dielectric material comprises the step of conformally depositing the blanket layer of at least one material selected from the group consisting of aluminum oxide (Al₂O₃), hafnium oxide (HfO₂), hafnium oxynitride (HfON), hafnium silicate (HfSiO₄), zirconium oxide (ZrO₂), zirconium silicate (ZrSiO₄), yttrium oxide (Y₂O₃), lanthanum oxide (La₂O₃), cerium oxide (CeO₂), titanium oxide (TiO₂), and combinations thereof.

12. The method of claim 8, further comprising, after the step of implanting and before the step of forming a conductive contact, the step of forming an additional spacer adjacent to the offset spacer.

13. The method of claim 8, further comprising the step of adjusting the type of fixed charge in a portion of the high-k dielectric material that overlies the spaced-apart impurity-doped extensions so that a threshold voltage in the portion of the spaced-apart impurity-doped extensions is lower than a threshold voltage in a channel region underlying the gate stack.

14. A method for fabricating an MOS transistor exhibiting low external resistance, the method comprising the steps of:
providing a semiconductor substrate having a surface of a first conductivity type thereon;
fabricating a gate stack overlying the semiconductor substrate;
depositing overlying the gate stack and the semiconductor substrate a layer of high-k spacer-forming material that results in a low interface trap density between the high-k spacer-forming material and the semiconductor substrate;
anisotropically etching the layer of high-k spacer-forming material to form a high-k offset spacer disposed adjacent to sidewalls of the gate stack;
implanting into the semiconductor substrate impurity dopants of a second conductivity type using the gate stack and the high-k offset spacer as an implantation mask;
forming an additional spacer proximate to the high-k offset spacer; and
depositing a metal silicide-forming material on the semiconductor substrate and heating the metal silicide-forming material to form metal silicide on the semiconductor substrate.

15. The method of claim 14, wherein the step of fabricating a gate stack comprises the steps of:
forming a layer of gate insulating material overlying the semiconductor substrate;
depositing a layer of gate electrode material overlying the layer of gate insulating material; and
etching the layer of gate electrode material and the layer of gate insulating material to form the gate stack having a gate insulator disposed on the semiconductor substrate and a gate electrode overlying the gate insulator.

16. The method of claim 15, further comprising, after the step of etching the layer of gate electrode material and the layer of gate insulating material and before the step of depositing a layer of high-k offset spacer-forming material, the step of laterally etching the gate insulator.

17. The method of claim 16, wherein the step of laterally etching the gate insulator comprises etching the gate insulator a distance, as measured from the sidewalls of the gate stack, in a range of about 3 nm.

18. The method of claim 14, wherein the step of depositing a layer of high-k spacer-forming material comprises the step of depositing a layer of at least one material selected from the group consisting of aluminum oxide (Al₂O₃), hafnium oxide (HfO₂), hafnium oxynitride (HfON), hafnium silicate (HfSiO₄), zirconium oxide (ZrO₂), zirconium silicate (ZrSiO₄), yttrium oxide (Y₂O₃), lanthanum oxide (La₂O₃), cerium oxide (CeO₂), titanium oxide (TiO₂), and combinations thereof.

19. The method of claim 14, further comprising, after the step of forming an additional spacer and before the step of depositing a metal silicide-forming material, the step of implanting into the semiconductor substrate impurity dopants of the second conductivity type using the gate stack, the high-k offset spacer, and the additional spacer as an implantation mask.

20. An MOS transistor comprising:
a gate insulator disposed on a semiconductor substrate;
a gate electrode overlying the gate insulator;
a high-k offset spacer disposed adjacent to sidewalls of the gate electrode, wherein the high-k offset spacer comprises a high-k material that results in low interface trap density between the high-k material and the semiconductor substrate;
source and drain extensions disposed within the semiconductor substrate and aligned with the gate electrode and the high-k offset spacer;
an additional spacer disposed adjacent to the high-k offset spacer; and
source and drain regions disposed within the semiconductor substrate and aligned with the gate electrode, the high-k offset spacer, and the additional spacer.
